(19) United States
(12) Patent Application Publication
(10) Pub. No.: US 2019/0081254 A1
(43) Pub. Date: Mar. 14, 2019

(54) DISPLAY SUBSTRATE, DISPLAY PANEL, DISPLAY DEVICE AND METHOD FOR MANUFACTURING THE SAME

(71) Applicant: BOE TECHNOLOGY GROUP CO, LTD., Beijing (CN)

(72) Inventor: Tao WANG, Beijing (CN)

(21) Appl. No.: 15/762,539

(22) PCT Filed: Jul. 20, 2017
(86) PCT No.: PCT/CN2017/093631

§ 371 Date: Mar. 22, 2018

(30) Foreign Application Priority Data
Mar. 13, 2017 (CN) 201710146766.4

(51) Int. Cl. H01L 51/00; H01L 51/52; H01L 51/56

(52) U.S. Cl. CPC H01L 51/0097; H01L 51/56; H01L 51/5246

(57) ABSTRACT

The present application relates to a display substrate, comprising a display device layer on one side of a flexible base substrate and a curve definition structure layer on an opposite side of the flexible base substrate. The curve definition structure layer at least comprises a first adhesive layer and a first definition film layer attached to each other. The first adhesive layer is located between the flexible base substrate and the first definition film layer, and comprises interruption regions. The present application further relates to a display panel, a display device, and a method for manufacturing a display substrate.

### DECLARATION OF PRIORITY

The present application claims the priority of the Chinese patent application No. 201710146766.4 filed on Mar. 13, 2017, the disclosure of which is incorporated herein by reference.

### TECHNICAL FIELD

The present disclosure relates to the field of display technologies, and in particular to a display substrate and a method for manufacturing the same, as well as a display panel and a display device comprising the same.

### BACKGROUND

Nowadays, curved display screens become more and more popular, wherein bendable display can be achieved by using a liquid crystal display (LCD) panel or an organic light emitting diode (OLED) display panel. Benefiting from the characteristic of self-luminance, it is easier for an OLED display manufactured on a flexible substrate to achieve bendable display with a smaller radius of curvature. Therefore, the manufacture of an OLED display panel comprising a flexible substrate has attracted wide attention, and an improved flexible substrate is required in order to obtain a better curve effect.

### SUMMARY

The present application attempts to propose an improved display substrate, display panel and display device, as well as method for manufacturing a display substrate, so as to satisfy requirements.

In one aspect, a display substrate is provided. The display substrate comprises a display device layer on one side of a flexible base substrate and a curve definition structure layer on an opposite side of the flexible base substrate. The curve definition structure layer at least comprises a first adhesive layer and a first definition film layer attached to each other. The first adhesive layer is located between the flexible base substrate and the first definition film layer, and comprises interruption regions. By arranging the curve definition structure layer on the display substrate, a better control over a curved part and a curve degree of the display substrate can be obtained.

In an optional embodiment, the first adhesive layer further comprises a plurality of first adhesive portions separated by the interruption regions. Besides, in a non-curved state, two adjacent first adhesive portions are spaced apart by about 20 millimeters to about 100 millimeters. In other words, in a non-curved state, the interruption regions have a width of about 20 millimeters to about 100 millimeters between two adjacent first adhesive portions. Thereby, the width of the interruption regions can be adjusted based on a size of the display substrate and a curve degree as desired.

In an optional embodiment, the curve definition structure layer further comprises a second definition film layer located between the first adhesive is layer and the flexible base substrate. In this embodiment, the second definition film layer can function as a protective film for the flexible base substrate at the same time.

In an optional embodiment, a thickness of the first definition film layer and/or the second definition film layer falls within the range of about 20 μm-150 μm. Further optionally, a thickness of the first adhesive layer falls within the range of about 5 μm-150 μm.

In an optional embodiment, on the opposite side of the flexible base substrate, a protective film layer is provided for protecting the flexible base substrate. Further optionally, the second definition film layer is the protective film layer.

In an optional embodiment, the opposite side of the flexible base substrate is provided with a protective film layer for protecting the flexible base substrate, and the curve definition structure layer is arranged on the protective film layer via a second adhesive layer.

In an optional embodiment, the interruption regions are located in an area corresponding to a non-display region of the display substrate. In particular, the interruption regions are located in an area corresponding to a control circuit region of the display substrate. As a result, the curved part can be located within the control circuit region. Obviously, in an alternative embodiment, the interruption regions are located in an area corresponding to a display region of the display substrate.

In a further optional embodiment, during assembly, the control circuit region is bent to be behind an effective display region of the display substrate via the interruption regions. This can achieve the goal of reducing the length of the final product.

In another optional embodiment, the interruption regions can be located in an effective display region of the display substrate.

In an optional embodiment, the first definition film layer and the second definition film layer have different flexural moduli. Further optionally, the flexural modulus of the first definition film layer is smaller than that of the second definition film layer.

In an optional embodiment, one or more imprinting or half-cutting lines are provided in an area of at least one of the first definition film layer and the second definition film layer corresponding to the interruption regions, and the imprinting or half-cutting lines extend in a direction perpendicular to a separation direction of the plurality of first adhesive portions (i.e., a width direction of the interruption regions).

In another aspect, a display panel is provided, comprising the display substrate as mentioned above.

In yet another aspect, a display device is provided, comprising the flexible display panel as mentioned above.

In still another aspect, a method for manufacturing a display substrate is provided, comprising: manufacturing a display device layer on one side of a flexible base substrate, and manufacturing a curve definition structure layer on an opposite side of the flexible base substrate. Specifically, the curve definition structure layer is provided with a first adhesive layer and a first definition film layer attached to each other. Besides, the first adhesive layer is located between the flexible base substrate and the first definition film layer, and comprises interruption regions.

In an optional embodiment, the curve definition structure layer is further provided with a second definition film layer located between the first adhesive layer and the flexible base substrate.

In an optional embodiment, the method further comprises: pre-imprinting or pre-half-cutting an area of at least one of the first definition film layer and the second definition film layer corresponding to the interruption regions, so as to form imprinting or half-cutting lines.

In an optional embodiment, the display substrate comprises a display region and a non-display region, and the interruption regions are located in an area corresponding to the non-display region. In this case, the method further comprises: bending the non-display region to be behind the display region by means of the interruption regions.

### BRIEF DESCRIPTION OF THE DRAWINGS

Drawings are included to provide further understanding of embodiments, and incorporated into the description to form part of the description. The drawings illustrating the embodiments are used to explain principles of the present disclosure together with depictions. Other embodiments and many expected advantages of the embodiments will be easily realized, because they will become better understood with reference to the detailed depictions as follows. Elements in the drawings are not necessarily drawn true to scale. Same reference signs refer to similar components.

FIG. 1 schematically shows the structure of a curve definition structure layer according to an embodiment of the present disclosure;

FIG. 2 is a schematic view of a curve definition structure layer in a curved state;

FIG. 3 is a schematic view of another curve definition structure layer in a curved state;

FIG. 4 schematically shows a display substrate provided with a curve definition structure layer according to an embodiment of the present disclosure;

FIG. 5 schematically shows a display substrate provided with a curve definition structure layer according to another embodiment of the present disclosure;

FIG. 6 schematically shows a display substrate provided with a curve definition structure layer according to yet another embodiment of the present disclosure; and

FIG. 7 schematically shows a flow diagram of a method for manufacturing a display substrate according to an embodiment of the present disclosure.

### DETAILED DESCRIPTION OF THE EMBODIMENTS

In the detailed depictions below, referring to the drawings, the drawings constitute part of the specific embodiments, and are shown by explanatory specific embodiments that can implement the present disclosure.

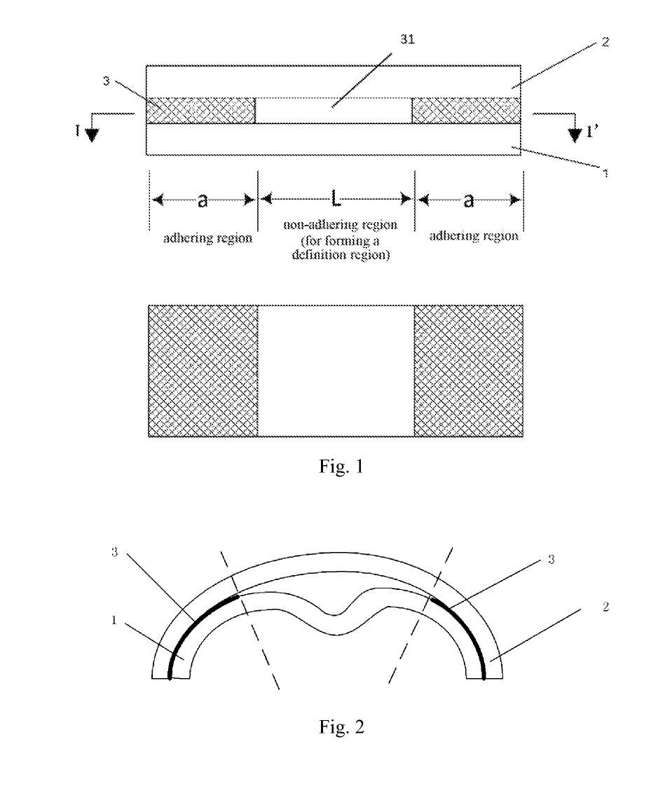

FIG. 1 shows the structure of a curve definition structure layer. The upper part of FIG. 1 is a side sectional view of the curve definition structure layer, and the lower part of FIG. 1 is a plan view of the curve definition structure layer in an I-I′ direction of FIG. 1. The curve definition structure layer can comprise a first definition film layer 1, a second definition film layer 2, and a first adhesive layer 3 for adhering the two definition film layers together. As can be seen, the first adhesive layer 3 is not spread all over between the first definition film layer 1 and the second definition film layer 2, but instead, it is provided with interruption regions 31. The interruption region 31 can also be called an adhesive-free region or a non-adhesive region, i.e., a region having no adhesive in the first adhesive layer 3. The interruption region 31 is used for defining a region that can be more easily bent than other regions. When the flexible display substrate is provided with such a curve definition structure, selection of a curved part of the flexible display panel as desired can be achieved. For example, a width L (i.e., a dimension along a horizontal direction in the drawing) of the interruption region 31 falls within the range of about 20-100 millimeters. By controlling the width L, the range of a curved region can be controlled as desired. Obviously, based on the environment in which the curve definition structure layer is actually used, the width L can have a value beyond the range of 20-100 millimeters. The first adhesive layer 3 can be made of polyurethane or a silicone material.

The thickness of the first definition film layer and the second definition film layer can fall within the range of 20 μm-50 μm, and the thickness of the first adhesive layer 3 can fall within the range of 5 μm-150 μm. The definition film layers can be made of any one of the following materials: phosphoenolpyruvate (PEP), polyethylene naphthalate (PEN), polyimide (PI) and so on. By controlling an area of the interruption regions 31 and further utilizing the mechanical performance (e.g., flexural modulus) of the definition film layers, control over the curvature radius or the curve degree of the curved region can be obtained. The two definition film layers can have different flexural moduli. For example, a definition film layer on an inner side of the curve can have a smaller flexural modulus than a definition film layer on an outer side, such that the definition film layer having a smaller flexural modulus can have more obvious pleats.

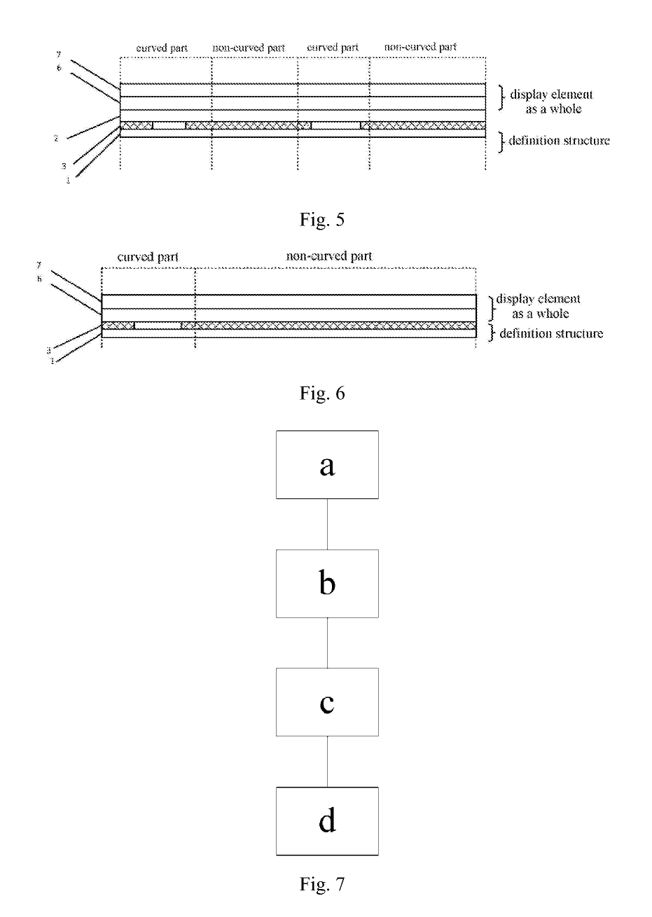

Besides, it should be understood that two or more interruption regions 31 can be arranged in the first adhesive layer 3 for the arrangement of two or more curved parts (e.g., as shown in FIG. 5).

FIG. 2 is a schematic view of a curve definition structure layer in a curved state. When the curve definition structure layer is bent, the definition film layer 2 on the outer side is subjected to a tensile force, and becomes curved as a whole; and the definition film layer 1 on the inner side is subjected to a compressive force, and generates pleat-like deformations. As can be seen, the part with the maximum curve is located at these deformations, i.e., in the interruption regions 31 as mentioned above.

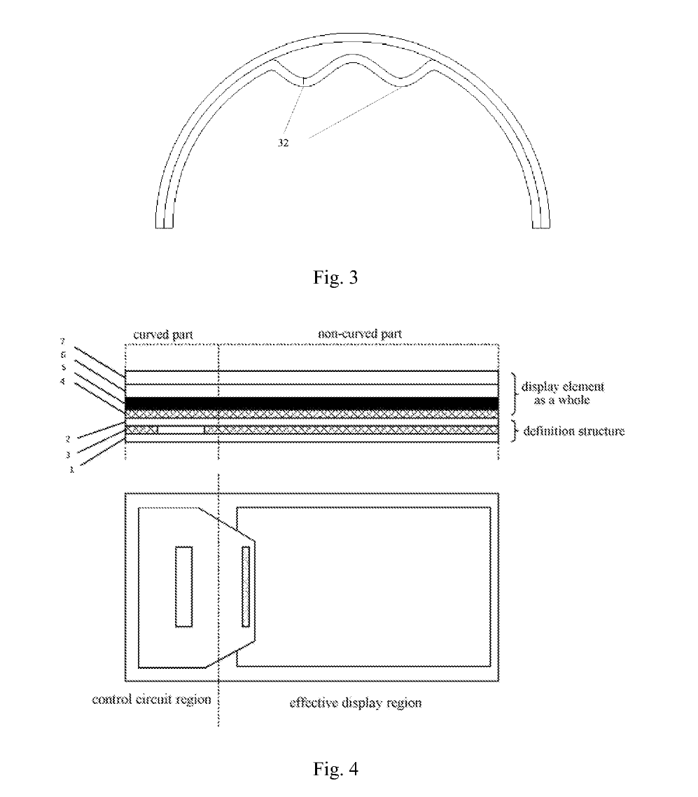

In an optional embodiment, as shown in FIG. 3, an area of the first definition film layer 1 and/or the second definition film layer 2 corresponding to the interruption regions 31 is pre-imprinted or pre-half-cut so as to form imprinting or half-cutting lines. The imprinting or the half-cutting lines extend in a direction perpendicular to a width direction of the interruption regions, i.e., in a direction perpendicular to the width direction. FIG. 3 shows a schematic curve view of another curve definition structure layer provided with two imprinting or half-cutting lines 32 (the first adhesive layer 3 is omitted). That is, in case that the first definition film layer 1 is provided with two imprinting lines, the first definition film layer 1 can generate two pleats when it is bent. This helps to achieve better control over the curve degree of the curved and deformed region.

FIG. 4 schematically shows a display substrate provided with a curve definition structure layer according to an embodiment of the present disclosure. As can be seen from FIG. 4, the display substrate can comprise a display device layer 7 located on a base substrate 6, and a curve definition structure layer located under a back protective film 5 of the base substrate 6, wherein the curve definition structure layer comprises a first definition film layer 1, a second definition film layer 2 and a first adhesive layer 3. The display device layer 7 can be an OLED display device. The base substrate is preferably a flexible base substrate. In this embodiment, the curve definition structure layers 1, 2 and 3 are adhered with the back protective film 5 under the base substrate 6 via an additional second adhesive layer 4. Therefore, by means of the curve definition structure layer, the curved position and the curve degree of the display substrate can be better controlled in this embodiment, and achieve better protection at a position where the display substrate needs to be bent. In an optional example, the interruption region 31 is arranged in a position corresponding to the non-display region (in particular, a control circuit region) of the display substrate (as shown in FIG. 4), such that the control circuit region can be better bent or even bent to the back of the display substrate. This helps to decrease a final length or width of the display device, and increase a visible area of the display device. For example, this can further reduce the thickness of the bezel. The back protective film 5 can be made of any one of the following materials: phosphoenolpyruvate (PEP), polyethylene naphthalate (PEN), polyimide (PI) and so on.

FIG. 5 schematically shows a display substrate provided with a curve definition structure layer according to another embodiment of the present disclosure. In this embodiment, two interruption regions 31 are arranged in the first adhesive layer 3 of the curve definition structure layer on the display substrate. Therefore, there can be two curved parts. Obviously, more curved parts can be arranged upon actual needs. Besides, this embodiment further differ from the embodiment as shown in FIG. 4 in that a definition film layer of the curve definition structure, in particular, the second definition film layer 2, functions as the back protective film of the base substrate 6. During manufacture of the display substrate, it is only necessary to add a definition film layer to the back of the base substrate 6, and then add a first adhesive layer 3 and a first definition film layer 1. Therefore, according to this embodiment, the cost can be saved, and the process can be simplified. In the meanwhile, it is also possible to control the curve degree by using different flexural moduli between the two definition film layers 1 and 2.

FIG. 6 schematically shows a display substrate provided with a curve definition structure layer according to yet another embodiment of the present disclosure. In this embodiment, the curve definition structure only comprises a first adhesive layer 3 and a first definition film layer 1, wherein the first adhesive layer 3 is directly arranged on the base substrate 6. This embodiment can further save the cost and simplify the process.

With the display substrate in the above embodiment, one can manufacture a display panel and a display device comprising the same, so as to achieve better control over the curve of the display panel and the display device.

FIG. 7 schematically shows a flow diagram of a method for manufacturing a display substrate according to an embodiment of the present disclosure. The method comprises steps as follows.

In Step a), a display device layer is manufactured on one side (i.e., a light emergent side) of a flexible base substrate.

In Step b), a curve definition structure layer is manufactured on an opposite side of the flexible base substrate (or on a back protective film of the flexible base substrate). The curve definition structure layer comprises a first definition film layer and a second definition film layer, as well as a first adhesive layer located between the first definition film layer and the second definition film layer. The first adhesive layer is located between the flexible base substrate and the first definition film layer, and comprises interruption regions. The curve definition structure layer can be manufactured on the opposite side of the flexible base substrate by adhering. In an optional example, the first definition film layer or the second definition film layer is used as the back protective film of the flexible base substrate.

The method can further comprise step c): pre-imprinting or pre-half-cutting an area of the first definition film layer and/or the second definition film layer corresponding to the interruption regions, so as to form imprinting or half-cutting lines. In an optional example, the flexible display substrate comprises a display region and a non-display region, and in particular a control circuit region, wherein the interruption regions are located in the control circuit region.

The method can further comprise step d): bending the control circuit region to be behind the effective display region by means of the interruption regions.

Although the method is divided into four steps as shown in FIG. 7, it should be realized that in actual applications, one or more steps can be omitted and some other steps can be added. Moreover, although the steps of the method are shown in a certain sequence in the drawing, it should be realized that the steps of the method can be executed in a different sequence than the one shown in the drawing, and can be executed in an opposite sequence or in parallel without deviating from the spirit of the present disclosure.

The above description relates to specific embodiments of the present application, but the protection scope of the present application shall not be limited thereto. Any variation or substitution, easily conceivable within the technical disclosure of the present application for a skilled person who is familiar with this technical field, shall fall within the protection scope of the present application. Therefore, the protection scope of the present application shall be subject to the protection scope of the claims.

In the depiction of the present application, it should be understood that directional or positional relations indicated by terms such as “up”, “down”, “inner” and “outer” are directional or positional relations shown on the basis of the drawings. They are used only for describing the present application and simplifying the depiction, instead of indicating or implying that the indicated device or element must be orientated specifically, or constructed and operated in a specific orientation. Therefore, all these terms should not be construed as limiting the present application. The wording “comprise” does not exclude the presence of elements or steps not listed in the claims. The wording “one” or “a” before an element does not exclude the presence of a plurality of such elements. The mere fact that certain measures are recited in mutually different dependent claims does not indicate that a combination of these measures cannot be used to advantage. No reference sign in the claims should be construed as limiting the scope.

1. A display substrate, comprising:
a display device layer on one side of a flexible base substrate; and
a curve definition structure layer on an opposite side of the flexible base substrate, wherein
the curve definition structure layer at least comprises a first adhesive layer and a first definition film layer attached to each other, and
the first adhesive layer is located between the flexible base substrate and the first definition film layer, and comprises interruption regions.

2. The display substrate according to claim 1, wherein
the first adhesive layer further comprises a plurality of first adhesive portions separated by the interruption regions, and
in a non-curved state, two adjacent first adhesive portions are spaced apart by about 20 millimeters to about 100 millimeters.

3. The display substrate according to claim 1, wherein the curve definition structure layer further comprises a second definition film layer located between the first adhesive layer and the flexible base substrate.

4. The display substrate according to claim 3, wherein the first definition film layer has a thickness of about 20 μm to about 150 μm.

5. The display substrate according to claim 3, wherein the second definition film layer has a thickness of about 20 μm to about 150 μm.

6. The display substrate according to claim 3, wherein the first adhesive layer has a thickness of about 5 μm to about 150 μm.

7. The display substrate according to claim 3, wherein on the opposite side of the flexible base substrate, a protective film layer is provided for protecting the flexible base substrate.

8. The display substrate according to claim 7, wherein the second definition film layer is the protective film layer.

9. The display substrate according to claim 3, wherein
on the opposite side of the flexible base substrate, a protective film layer is provided for protecting the flexible base substrate, and
the curve definition structure layer is arranged on the protective film layer via a second adhesive layer.

10. The display substrate according to claim 1, wherein the interruption regions are located in an area corresponding to a non-display region of the display substrate.

11. The display substrate according to claim 1, wherein the interruption regions are located in an area corresponding to a display region of the display substrate.

12. The display substrate according to claim 3, wherein the first definition film layer and the second definition film layer have different flexural moduli.

13. The display substrate according to claim 12, wherein the flexural modulus of the first definition film layer is smaller than that of the second definition film layer.

14. The display substrate according to claim 2, wherein
imprinting or half-cutting lines are provided in an area of at least one of the first definition film layer and the second definition film layer corresponding to the interruption regions, and
the imprinting or the half-cutting lines extend in a direction perpendicular to a separation direction of the plurality of first adhesive portions.

15. A display panel, comprising the display substrate according to claim 1.

16. A display device, comprising the display panel according to claim 15.

17. A method for manufacturing a display substrate, comprising:
manufacturing a display device layer on one side of a flexible base substrate; and
manufacturing a curve definition structure layer on an opposite side of the flexible base substrate, wherein
the curve definition structure layer is provided with a first adhesive layer and a first definition film layer attached to each other, and
the first adhesive layer is located between the flexible base substrate and the first definition film layer, and comprises interruption regions.

18. The method according to claim 17, wherein the curve definition structure layer is further provided with a second definition film layer located between the first adhesive layer and the flexible base substrate.

19. The method according to claim 17, wherein the method further comprises: pre-imprinting or pre-half-cutting an area of at least one of the first definition film layer and the second definition film layer corresponding to the interruption regions, so as to form imprinting or half-cutting lines.

20. The method according to claim 17, wherein
the display substrate comprises a display region and a non-display region, and the interruption regions are located in an area corresponding to the non-display region, and
the method further comprises: bending a control circuit region to be behind the display region by means of the interruption regions.
